(19) United States
(12) Patent Application Publication
(10) Pub. No.: US 2025/0287793 A1
(43) Pub. Date: Sep. 11, 2025

(54) DISPLAY PANEL AND PREPARATION METHOD THEREFOR, AND DISPLAY DEVICE

(71) Applicants: Chongqing BOE Display Technology Co.,Ltd., Chongqing (CN); BOE Technology Group Co., Ltd., Beijing (CN)

(72) Inventors: Ni YANG, Beijing (CN); Xiangyi LI, Beijing (CN); Rui WANG, Beijing (CN); Hai ZHENG, Beijing (CN)

(21) Appl. No.: 18/860,634

(22) PCT Filed: Jan. 22, 2024
(86) PCT No.: PCT/CN2024/073442

§ 371 Date: Oct. 26, 2024

(30) Foreign Application Priority Data
Feb. 28, 2023 (CN) 202310200006.2

(51) Int. Cl. H10K 59/131

(52) U.S. Cl. CPC H10K 59/131

(57) ABSTRACT

A display panel and a preparation method therefor, and a display device. The display panel (100) comprises a substrate (300) and N conductive layers, the N conductive layers are sequentially arranged on the substrate (300) in a direction away from the substrate (300), and each of the N conductive layers comprises at least one conductive wire extending at least in a first direction, where N is an integer greater than or equal to 3. Regarding the portion of the at least one conductive wire in each conductive layer that extends in the first direction and the portion of the at least one conductive wire in each of the remaining conductive layers that extends in the first direction, orthographic projections of said extending portions on the substrate (300) are offset from each other in a second direction and have an overlap, and the second direction intersects with the first direction.

### CROSS-REFERENCE TO RELATED APPLICATION

The present application is a U.S. National Phase Entry of International Application No. PCT/CN2024/073442 having an international filing date of Jan. 22, 2024, which claims priority to Chinese patent application No. 202310200006.2, filed to the CNIPA on Feb. 28, 2023 and entitled “Display Panel and Preparation Method Therefor, and Display Device”. Contents of the above-identified applications are incorporated into the present application by reference.

### TECHNICAL FIELD

The present disclosure relates to, but is not limited to, the field of display technologies, and particularly relates to a display panel and a manufacturing method for the display panel, and a display apparatus.

### BACKGROUND

Organic Light Emitting Diodes (OLED) and Quantum-dot Light Emitting Diodes (QLED) are active light emitting display devices, and have advantages such as self-illumination, a wide viewing angle, a high contrast ratio, low power consumption, an extremely high reaction speed, lightness and thinness, flexibility, and low cost. An under-display camera technology is a novel technology proposed for increasing a screen-to-body ratio of a display apparatus.

### SUMMARY

The following is a summary of subject matters described herein in detail. This summary is not intended to limit the protection scope of claims.

Embodiments of the present disclosure provide a display panel, a manufacturing method for the display panel, and a display apparatus.

In one aspect, an embodiment of the present disclosure provides a display panel. The display panel includes a base substrate and N conductive layers. The N conductive layers are sequentially provided on the base substrate in a direction away from the base substrate. Each conductive layer of the N conductive layers includes at least one conductive line extending at least in a first direction, and N is an integer greater than or equal to 3. An orthographic projection of a portion of at least one conductive line extending in the first direction in each conductive layer on the base substrate and an orthographic projection of a portion of at least one conductive line extending in the first direction in remaining conductive layers on the base substrate are staggered and overlap in a second direction, and the second direction intersects with the first direction.

In an exemplary embodiment, an orthographic projection of one conductive line located in a nth conductive layer on the base substrate overlaps with an orthographic projection of one conductive line located in a (n−1)th conductive layer on the base substrate and an orthographic projection of one conductive line located in a (n+1)th conductive layer on the base substrate, and the orthographic projection of the conductive line located in the (n−1)th conductive layer on the base substrate does not overlap with the orthographic projection of the conductive line located in the (n+1)th conductive layer on the base substrate, in which n is an integer greater than or equal to 2 and less than or equal to N−1.

In an exemplary embodiment, an overlapping length of the orthographic projection of the conductive line located in the nth conductive layer on the base substrate and the orthographic projection of the conductive line located in the (n−1)th conductive layer on the base substrate in the second direction is equal to an overlapping length of the orthographic projection of the conductive line located in the nth conductive layer on the base substrate and the orthographic projection of the conductive line located in the (n+1)th conductive layer on the base substrate in the second direction.

In an exemplary embodiment, the overlapping length of the orthographic projection of the conductive line located in the nth conductive layer on the base substrate and the orthographic projection of the conductive line located in the (n−1)th conductive layer on the base substrate in the second direction is

$$k 1 \times ( \frac{1}{2} W - \frac{1}{4} S ) ,$$

in which k1 is a first process parameter, W is a line width parameter, and S is a line spacing parameter.

In an exemplary embodiment, an orthographic projection of one conductive line located in a mth conductive layer on the base substrate overlaps with an orthographic projection of one conductive line located in a (m−1)th conductive layer on the base substrate and an orthographic projection of one conductive line located in a (m−2)th conductive layer on the base substrate, and the orthographic projection of the conductive line located in the (m−1)th conductive layer on the base substrate does not overlap with the orthographic projection of the conductive line located in the (m−2)th conductive layer on the base substrate, in which m is an integer greater than or equal to 3 and less than or equal to N.

In an exemplary embodiment, an overlapping length of the orthographic projection of the conductive line located in the mth conductive layer on the base substrate and the orthographic projection of the conductive line located in the (m−1)th conductive layer on the base substrate in the second direction is less than an overlapping length of the orthographic projection of the conductive line located in the mth conductive layer on the base substrate and the orthographic projection of the conductive line located in the (m−2)th conductive layer on the base substrate in the second direction.

In an exemplary embodiment, the overlapping length of the orthographic projection of the conductive line located in the mth conductive layer on the base substrate and the orthographic projection of the conductive line located in the (m−1)th conductive layer on the base substrate in the second direction is equal to a half of the overlapping length of the orthographic projection of the conductive line located in the mth conductive layer on the base substrate and the orthographic projection of the conductive line located in the (m−2)th conductive layer on the base substrate in the second direction.

In an exemplary embodiment, the overlapping length of the orthographic projection of the conductive line located in the mth conductive layer on the base substrate and the orthographic projection of the conductive line located in the (m−1)th conductive layer on the base substrate in the second direction is

$$k 2 \times ( W - \frac{1}{2} S ) ,$$

in which k2 is a second process parameter, W is a line width parameter, and S is a line spacing parameter.

In an exemplary embodiment, line widths of multiple conductive lines in at least one conductive layer are equal, and line spacings of adjacent conductive lines are equal.

In an exemplary embodiment, the line widths of the multiple conductive lines in the at least one conductive layer are equal to the line spacings of adjacent conductive lines.

In an exemplary embodiment, line widths of conductive lines in different conductive layers are equal, and line spacings of adjacent conductive lines in different conductive layers are equal.

In an exemplary embodiment, the display panel further includes an insulation layer between two adjacent conductive layers, and multiple insulation layers have equal thicknesses.

In an exemplary embodiment, a thickness of the conductive layer is less than a thickness of the insulation layer adjacent to the conductive layer.

In an exemplary embodiment, the display panel includes a display area; the display area includes a first area and a second area; and an orthographic projection of the first area on the base substrate does not overlap with an orthographic projection of the second area on the base substrate.

The display panel further includes a circuit structure layer and a light emitting structure layer provided on the base substrate, the light emitting structure layer is located on a side of the circuit structure layer away from the base substrate, and the N conductive layers are located between the circuit structure layer and the light emitting structure layer. The circuit structure layer includes multiple first pixel driving circuits and multiple second pixel driving circuits located in the first area, and the light emitting structure layer includes multiple first light emitting devices located in the first area and multiple second light emitting devices located in the second area.

At least one first pixel driving circuit of the multiple first pixel driving circuits is electrically connected to at least one first light emitting device of the multiple first light emitting devices, and at least one second pixel driving circuit of the multiple second pixel driving circuits is electrically connected to at least one second light emitting device of the multiple second light emitting devices by at least one conductive line in the N conductive layers.

In an exemplary embodiment, a value of N is 3. An orthographic projection of one conductive line located in a second conductive layer on the base substrate overlaps with an orthographic projection of one conductive line located in a first conductive layer on the base substrate and an orthographic projection of one conductive line located in a third conductive layer on the base substrate, and the orthographic projection of the conductive line located in the first conductive layer on the base substrate does not overlap with the orthographic projection of the conductive line located in the third conductive layer on the base substrate. The orthographic projection of the conductive line located in the third conductive layer on the base substrate overlaps with an orthographic projection of another conductive line located in the first conductive layer on the base substrate, and the conductive line and the another conductive line located in the first conductive layer are adjacent to each other in the second direction.

In an exemplary embodiment, an overlapping length of the orthographic projection of the conductive line located in the second conductive layer on the base substrate and the orthographic projection of the conductive line located in the first conductive layer on the base substrate in the second direction is equal to an overlapping length of the orthographic projection of the conductive line located in the second conductive layer on the base substrate and the orthographic projection of the conductive line located in the third conductive layer on the base substrate in the second direction.

An overlapping length of the orthographic projection of the conductive line located in the third conductive layer on the base substrate and the orthographic projection of the another conductive line located in the first conductive layer on the base substrate in the second direction is equal to two times of the overlapping length of the orthographic projection of the conductive line located in the second conductive layer on the base substrate and the orthographic projection of the conductive line located in the first conductive layer on the base substrate in the second direction.

In an exemplary embodiment, an overlapping length of the orthographic projection of the conductive line located in the second conductive layer on the base substrate and the orthographic projection of the conductive line located in the first conductive layer on the base substrate in the second direction is denoted as O₁. An overlapping length of the orthographic projection of the conductive line located in the second conductive layer on the base substrate and the orthographic projection of the conductive line located in the third conductive layer on the base substrate in the second direction is denoted as O₂. An overlapping length of the orthographic projection of the conductive line located in the third conductive layer on the base substrate and the orthographic projection of the another conductive line located in the first conductive layer on the base substrate in the second direction is denoted as O₃. A thickness of an insulation layer between the first conductive layer and the second conductive layer is denoted as D₁; a thickness of an insulation layer between the second conductive layer and the third conductive layer is denoted as D₂; a thickness of an insulation layer between the first conductive layer and the third conductive layer is denoted as D₃; then O₁, O₂, O₃, D₁, D₂ and D₃ satisfy the following equations:

$$\frac{{O}_{1}}{{D}_{1}} + \frac{{O}_{3}}{{D}_{3}} = \frac{{O}_{1}}{{D}_{1}} + \frac{{O}_{2}}{{D}_{2}} = \frac{{O}_{2}}{{D}_{2}} + \frac{{O}_{3}}{{D}_{3}} .$$

In another aspect, an embodiment of the present disclosure provides a display apparatus, including the display panel described in any of the above embodiments.

In another aspect, an embodiment of the present disclosure provides a manufacturing method for a display panel, which is used for manufacturing the display panel according to any one of the above embodiments. The manufacturing method includes: sequentially forming N conductive layers on a side of a base substrate. Each conductive layer of the N conductive layers includes at least one conductive line extending at least in a first direction, and N is an integer greater than or equal to 3. An orthographic projection of a portion of at least one conductive line extending in the first direction in each conductive layer on the base substrate and an orthographic projection of a portion of at least one conductive line extending in the first direction in remaining conductive layers on the base substrate are staggered and overlap in a second direction, and the second direction intersects with the first direction.

In a display panel provided by an embodiment of the present disclosure, an orthographic projection of a portion of at least one conductive line extending in the first direction in each conductive layer of N conductive layers on the base substrate and an orthographic projection of a portion of at least one conductive line extending in the first direction in remaining conductive layers on the base substrate are staggered and overlap in the second direction, so as to improve the difference between multiple coupling capacitances generated by the multiple conductive lines in the N conductive layers and improve the display quality of the display panel.

Other aspects of the present disclosure may be comprehended after the drawings and the detailed description are read and understood.

### BRIEF DESCRIPTION OF DRAWINGS

Accompanying drawings are intended to provide further understanding of technical solutions of the present disclosure and form a part of the specification, and are used to explain the technical solutions of the present disclosure together with embodiments of the present disclosure, but do not form limitations on the technical solutions of the present disclosure. Shapes and sizes of one or more components in the drawings do not reflect actual scales, but are only intended to schematically describe contents of the present disclosure.

FIG. 1 is a schematic three-dimensional view of a display apparatus according to an embodiment of the present disclosure.

FIG. 2 is a schematic front view of a display panel according to an embodiment of the present disclosure.

FIG. 3 is a partial schematic view of a display panel according to an embodiment of the present disclosure.

FIG. 4 is a schematic partial top view of a display panel.

FIG. 5 is a schematic cross-sectional view of the display panel taken along A-A direction in FIG. 4.

FIG. 6 is a schematic partial top view of a display panel according to an embodiment of the present disclosure.

FIG. 7 is a schematic cross-sectional view of the display panel taken along B-B direction in FIG. 6.

### DETAILED DESCRIPTION

The embodiments of the present disclosure will be described below with reference to the drawings in detail. Implementation may be implemented in multiple different forms. Those of ordinary skills in the art may easily understand such a fact that implementations and contents may be transformed into one or more forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals such as “first”, “second” and “third” in the present disclosure are set to avoid confusion between constituent elements, but not intended for restriction in quantity. In the present disclosure, “a plurality of/multiple” means two or more than two.

In the present disclosure, for convenience, wordings indicating orientation or positional relationship such as “middle”, “upper”, “lower”, “front”, “rear”, “vertical”, “horizontal”, “top”, “bottom”, “inner” and “outer” are employed to explain positional relationship between the constituent elements with reference to the accompanying drawings, they are employed for ease of description of the specification and simplification of the description only, but do not indicate or imply that the referred apparatus or element must have a particular orientation, or is constructed and operate in a particular orientation, and therefore cannot be construed as limitations on the present disclosure. The positional relationships between the constituent elements are changed as appropriate based on directions according to which the constituent elements are described. Therefore, appropriate replacements based on situations are allowed, which is not limited to the expressions in the specification.

In the present disclosure, the terms “mounting”, “coupling” and “connection” are to be understood broadly, unless otherwise expressly specified and defined. For example, it may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand meanings of the aforementioned terms in the present disclosure according to situations.

In the present disclosure, “electric connection” includes a case where constituent elements are connected through an element with a certain electrical action. The “element with a certain electrical effect” is not particularly limited as long as electrical signals between the connected constituent elements may be transmitted. Examples of the “element with a certain electrical effect” not only include electrodes and wirings, but also include switching elements such as transistors, resistors, inductors, capacitors, other elements with one or more functions, etc.

In the present disclosure, a transistor refers to an element including at least three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. In the present disclosure, the channel region refers to a region through which a current mainly flows.

In the present disclosure, a first pole may be a drain electrode and a second pole may be a source electrode, or a first pole may be a source electrode and a second pole may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the present disclosure.

In the present disclosure, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 850 and below 95°.

In the present disclosure, “film” and “layer” are interchangeable. For example, a “conductive layer” may be replaced with a “conductive film” sometimes. Similarly, an “insulation film” may be replaced with an “insulation layer” sometimes.

In the present disclosure, “about” or “approximately” means that a boundary is defined not so strictly and numerical values within process and measurement error ranges are allowed.

Triangle, rectangle, trapezoid, pentagon, hexagon or the like in the present disclosure are not strictly defined, and they may be approximate triangle, rectangle, trapezoid, pentagon, hexagon, and the like. There may be some small deformations caused by tolerance, and there may be chamfer, arc edge, deformation, or the like.

A “light transmittance” in the present disclosure refers to an ability of light to pass through a medium, and is a percentage of luminous flux passing through a transparent or translucent body to its incident luminous flux.

At least one embodiment of the present disclosure provides a display apparatus, including a display panel. The display apparatus may be a product having an image (including a still image or a moving image, where the moving image may be a video) display function. For example, the display apparatus may be any one of a display, a television, a billboard, a digital photo frame, a laser printer with display function, a telephone, a mobile phone, a picture screen, a personal digital assistant (PDA), a digital camera, a portable camcorder, a viewfinder, a navigator, a vehicle, a large-area wall, an information inquiry equipment (such as business inquiry equipment in e-government, banks, hospitals, power departments), a monitor, or the like. As another example, the display apparatus may be a micro-display, any one of a Virtual Reality (VR) device or an Augmented Reality (AR) device including the micro-display, or the like.

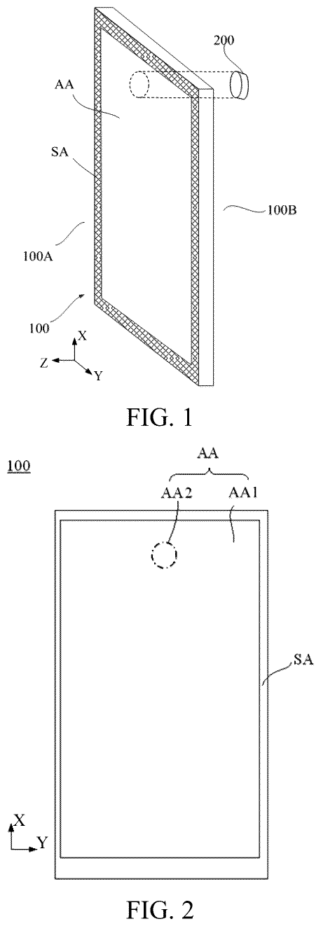

FIG. 1 is a schematic three-dimensional view of a display apparatus according to an embodiment of the present disclosure. As shown in FIG. 1, the display apparatus may include a display panel 100 and a sensor 200. The display panel 100 may be a flat panel for displaying images. The display panel 100 may be referred to as a screen, and may be, such as a liquid crystal display panel, an Organic Light Emitting Diode (OLED) display panel. For example, the sensor 200 may be an infrared sensor, an ultrasonic sensor, a Light Detection and Ranging (LIDAR) sensor, a Radar sensor, a camera sensor, or the like.

In an exemplary embodiment, as shown in FIG. 1, the display panel 100 may have a display side 100A and a non-display side 100B. The display side 100A may be a side on which the display panel 100 can display an image. When a human eye is on the display side 100A, the image displayed on the display panel 100 can be viewed. The non-display side 100B is opposite to the display side 100A. The sensor 200 may be provided on the non-display side 100B of the display panel 100 and therefore the sensor 200 may be referred to as an under-screen sensor. Since the sensor 200 needs to receive an optical signal transmitted from the outside through the display panel 100, the display panel 100 needs to have a higher light transmittance in an area corresponding to the sensor 200. The display panel in an embodiment of the present disclosure is not only applicable to a display apparatus with a Full Display with Camera (FDC), but also may be applied to other display panels with multiple conductive layer cables.

In an exemplary embodiment, as shown in FIG. 1, the display panel 100 may have a display area AA and a peripheral area SA. As shown in FIG. 1, an X direction may be an extension direction of one side edge of the display area AA, for example, an extension direction of a long side edge. A Y direction may be an extension direction of another side edge of the display area AA, for example, an extension direction of a short side edge. A Z direction may be a vertical direction of the display area AA. In an embodiment of the present disclosure, the Z direction is also a thickness direction of the display panel.

FIG. 2 is a schematic front view of a display panel according to an embodiment of the present disclosure. As shown in FIG. 2, the peripheral area SA may be located on at least a side outside the display area AA. By way of example, the peripheral area SA may be located on a side outside the display area AA. Alternatively, the peripheral area SA may be located on the periphery outside the display area AA, that is, the periphery includes the upper and lower sides and the left and right sides.

As shown in FIG. 2, the display area AA may include a first area AA1 and a second area AA2 that do not overlap each other. The first area AA1 may be referred to as a sensor non-corresponding area. The second area AA2 may be referred to as a sensor corresponding area. A light transmittance of the second area AA2 is higher than a light transmittance of the first area AA1. An orthographic projection of the sensor 200 on the display panel 100 at least partially overlaps with the second area AA2 so that more light can pass through the display panel 100 and be received by the sensor 200. By way of example, a portion of the orthographic projection of the sensor 200 on the display panel 100 is located in the second area AA2. Alternatively, an entire orthographic projection of the sensor 200 on the display panel 100 is located in the second area AA2. Alternatively, an orthographic projection of a photosensitive window of the sensor 200 on the display panel 100 is located in the second area AA2.

In an exemplary embodiment, the first area AA1 may be an area other than the second area AA2 in the display area AA.

In an exemplary embodiment, the first area AA1 may surround at least one side of the second area AA2. By way of example, the second area AA2 may be located in the middle of the top of the display area AA, and the first area AA1 may surround the second area AA2. By way of example, the second area AA2 may be located at other positions such as an upper left corner or an upper right corner of the display area AA, and the present disclosure is not limited thereto.

In an exemplary embodiment, the display area AA may be a rectangular shape, for example a rounded rectangular shape. The second area AA2 may be circular, elliptical, rectangular, pentagonal, hexagonal, or the like, and the present disclosure is not limited thereto.

In an exemplary embodiment, the display area AA may be provided with multiple sub-pixels. A sub-pixel may be a smallest part with controllable brightness. At least one sub-pixel may include a pixel driving circuit and a light emitting device. The pixel driving circuit may be electrically connected to the light emitting device and configured to drive a light emitting device with which it is electrically connected to emit light. The pixel driving circuit may include multiple transistors and at least one capacitor. For example, the pixel driving circuit may have a 3T1C, 4T1C, 5T1C, 5T2C, 6T1C, 7T1C, or 8T1C structure. In the above circuit structures, T refers to a thin film transistor, C refers to a capacitor, a number before T represents a quantity of thin film transistors in the circuit, and a number before C represents a quantity of capacitors in the circuit.

In an exemplary embodiment, multiple transistors in the pixel driving circuit may be P-type transistors, or may be N-type transistors. Usage of same type of transistors in the pixel driving circuit may simplify a process flow, reduce a process difficulty of the display substrate, and improve a yield of a product. In some other examples, the multiple transistors in the pixel driving circuit may include a P-type transistor and an N-type transistor.

In an exemplary embodiment, for the multiple transistors in the pixel driving circuit, a low temperature poly-silicon thin film transistor may be adopted, or an oxide thin film transistor may be adopted, or a low temperature poly-silicon thin film transistor and an oxide thin film transistor may be adopted. Low Temperature Poly-Silicon (LTPS) is adopted for an active layer of a low temperature poly-silicon thin film transistor and an oxide semiconductor (Oxide) is adopted for an active layer of an oxide thin film transistor. The low temperature poly-silicon thin film transistor has advantages such as a high migration rate and fast charging, and the oxide thin film transistor has advantages such as a low leakage current. The low temperature poly-silicon thin film transistor and the oxide thin film transistor are integrated on one display substrate, that is, an LTPS+Oxide (LTPO) display substrate, which can utilize advantages of both the low temperature poly-silicon thin film transistor and the oxide thin film transistor, achieve low-frequency driving, reduce power consumption, and improve display quality.

In an exemplary embodiment, the light emitting device may be any one of a Light Emitting Diode (LED), an Organic Light Emitting Diode (OLED), a Quantum Dot Light Emitting Diodes (QLED), a micro LED (a mini-LED or a micro-LED), and the like. By way of example, the light emitting device may be an OLED, and the light emitting device emits red light, green light, blue light, or white light, and the like under driving by its corresponding pixel driving circuit. A color of light emitted from the light emitting device may be determined as required. By way of example, the light emitting device may include an anode, a cathode, and an organic emitting layer provided between the anode and the cathode. The anode of the light emitting device may be electrically connected to a corresponding pixel driving circuit, and the present disclosure is not limited thereto.

In an exemplary embodiment, one pixel unit of the display area AA may include three sub-pixels, and the three sub-pixels may be a red sub-pixel, a green sub-pixel, and a blue sub-pixel, respectively, and the present disclosure is not limited thereto.

In an exemplary embodiment, one pixel unit may include four sub-pixels, and the four sub-pixels may be a red sub-pixel, a green sub-pixel, a blue sub-pixel, and a white sub-pixel, respectively.

In an exemplary embodiment, a shape of a light emitting device may be a rectangle, a diamond, a pentagon, or a hexagon. When one pixel unit includes three sub-pixels, light emitting devices of the three sub-pixels may be horizontally arranged, vertically arranged, or in a manner like a Chinese character “ [symbol] ”. When one pixel unit includes four sub-pixels, the light emitting devices of the four sub-pixels may be horizontally arranged, vertically arranged, or square arranged, and the present disclosure is not limited thereto.

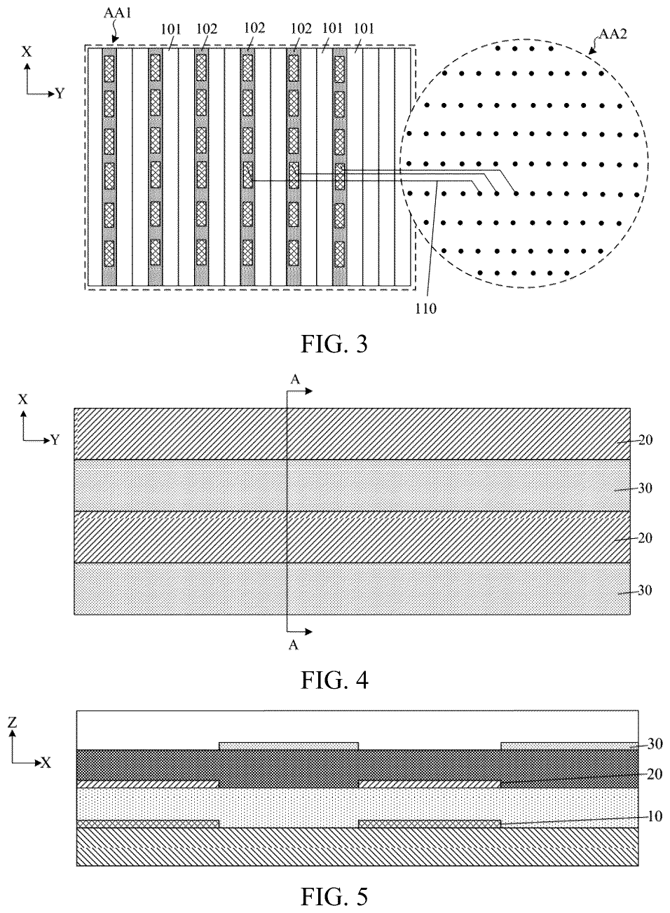

FIG. 3 is a partial schematic view of a display panel according to an embodiment of the present disclosure. As shown in FIG. 3, an area occupied by one pixel driving circuit may be referred to as one sub-pixel region. The first area AA1 may include multiple sub-pixel regions arranged in an array. The sub-pixel regions within the first area AA1 may include a normal sub-pixel region 101 and a dummy sub-pixel region 102. The normal sub-pixel region 101 may be provided with a first pixel driving circuit. A first light emitting device electrically connected to the first pixel driving circuit and the first pixel driving circuit may both be located in the first area AA1, and all or a portion of the first light emitting device may be located in the normal sub-pixel region 101. The dummy sub-pixel region 102 may be provided with a second pixel driving circuit or an invalid pixel driving circuit, and a second light emitting device electrically connected to the second pixel driving circuit may be located in the second area AA2. An arrangement of the invalid pixel driving circuit is conducive to improving uniformity of components of multiple film layers in an etching process. For example, a structure of the invalid pixel driving circuit may be substantially the same as that of the first pixel driving circuit or the second pixel driving circuit of a row or column where the invalid pixel driving circuit is located, except that invalid pixel driving circuit is not electrically connected to any light emitting device.

In an exemplary embodiment, as shown in FIG. 3, the second area AA2 may include multiple second light emitting devices arranged in an array. At least one second light emitting device in the second area AA2 may be electrically connected to the second pixel driving circuit in the dummy sub-pixel region 102 in the first area AA1, and be driven by the second pixel driving circuit to emit light.

As shown in FIG. 3, at least one second pixel driving circuit in the dummy sub-pixel region 102 in the first area AA1 may be electrically connected to at least one second light emitting device in the second area AA2 by at least one conductive line 110. By way of example, each second light emitting device in the second area AA2 may be electrically connected to a second pixel driving circuit in a dummy sub-pixel region 102 in the first area AA1 by at least one conductive line 110. By providing the second pixel driving circuit for driving the second light emitting device in the first area AA1, shielding of light by the pixel driving circuit is reduced, thereby increasing the light transmittance of the second area AA2.

In an exemplary embodiment, as shown in FIG. 3, the second area AA2 may include multiple second light emitting devices, and the first area AA1 may include multiple first light emitting devices and multiple pixel driving circuits. The multiple pixel driving circuits may include multiple first pixel driving circuits, multiple second pixel driving circuits, multiple invalid pixel driving circuits, and the like. At least one second pixel driving circuit of the multiple second pixel driving circuits may be electrically connected to at least one second light emitting device of the multiple second light emitting devices by at least one conductive line 110, and an orthographic projection of the at least one second pixel driving circuit on a base substrate does not overlap with an orthographic projection of the at least one second light emitting device on the base substrate. At least one second pixel driving circuit may be configured to provide a drive signal to a second light emitting device, with which the second pixel driving circuit is electrically connected, to drive the second light emitting device to emit light. At least one first pixel driving circuit of the multiple first pixel driving circuits and at least one first light emitting device of the multiple first light emitting devices may be electrically connected. An orthographic projection of the at least one first pixel driving circuit on the base substrate may at least partially overlap with an orthographic projection of the at least one first light emitting device on the base substrate. One end of the conductive line 110 may be electrically connected to a second pixel driving circuit and the other end of the conductive line 110 may be electrically connected to a second light emitting device. The conductive line 110 may extend from the first area AA1 to the second area AA2, which is not limited by the present disclosure.

In an exemplary embodiment, as shown in FIG. 3, since the first area AA1 is provided with not only the first pixel driving circuits electrically connected to the first light emitting devices, but also the second pixel driving circuits electrically connected to the second light emitting devices, a quantity of the pixel driving circuits may be greater than a quantity of the first light emitting devices in the first area AA1. In an embodiment of the present disclosure, as shown in FIG. 3, a region where the second pixel driving circuit is provided may be obtained by reducing a size of a first pixel driving circuit in the Y direction. For example, a size of the pixel driving circuit in the Y direction may be less than a size of the first light emitting device in the Y direction. In an embodiment of the present disclosure, as shown in FIG. 3, every original “a” columns of pixel driving circuits may be compressed in the Y direction, thereby adding an arrangement space for another column of pixel driving circuits, and the space occupied by the “a” columns of pixel driving circuits before compression and the space occupied by the “a+1” columns of pixel driving circuits after compression may be the same. Herein, a may be an integer greater than 1. For example, a may be equal to 2, or 3, or 4, or 7, or the like.

In an exemplary embodiment, the original “b” rows of pixel driving circuits may be compressed in the X direction, thereby adding an arrangement space for another row of pixel driving circuits, and the space occupied by the “b” rows of pixel driving circuits before compression and the space occupied by the “b+1” rows of pixel driving circuits after compression are the same. Herein, b may be an integer greater than 1. Alternatively, the region in which the second pixel driving circuit is provided may be obtained by reducing sizes of the first pixel driving circuit in the X direction and the Y direction.

In an exemplary embodiment, a row of light emitting devices may mean that pixel driving circuits connected to the row of light emitting devices are all connected to one same gate line (for example, a scan line). A row of pixel driving circuits may mean that all of the pixel driving circuits in the row are connected to a same gate line, and the present disclosure is not limited thereto.

In an exemplary embodiment, the display panel includes a base substrate and a circuit structure layer located on a side of the base substrate. The circuit structure layer may include at least one first pixel driving circuit and at least one second pixel driving circuit. The circuit structure layer may be located between the base substrate and the conductive line.

In an exemplary embodiment, the display panel may further include a light emitting structure layer located on a side of the multiple conductive lines away from the base substrate. The light emitting structure layer may include at least one first light emitting device and at least one second light emitting device.

FIG. 4 is a schematic partial top view of a display panel. FIG. 5 is a schematic cross-sectional view of the display panel taken along A-A direction in FIG. 4. FIGS. 4 and 5 illustrate a design and arrangement of multiple conductive lines. For example, the multiple conductive lines of the display panel may be located in three conductive layers (such as a first conductive layer, a second conductive layer, and a third conductive layer sequentially provided in a direction away from the base substrate), the first conductive layer may include at least one first connection line 10, the second conductive layer may include at least one second connection line 20, and the third conductive layer may include at least one third connection line 30. An orthographic projection of an extension portion of the second connection line 20 in the Y direction on the base substrate may cover an orthographic projection of an extension portion of the first connection line 10 in the Y direction on the base substrate, and an orthographic projection of an extension portion of the third connection line 30 in the Y direction on the base substrate does not overlap with an orthographic projection of the extension portions of the first connection line 10 and the second connection line 20 in the Y direction on the base substrate.

In some implementations, since the second light emitting device of the second area is electrically connected to the second pixel driving circuit of the first area by the conductive line, display uniformity of the second area is affected by a capacitance of the conductive line. In some examples, by adjusting a compression ratio of the pixel driving circuits in the first area and adjusting a priority order in which the second light emitting devices with different colors in the second area are connected to the second pixel driving circuit, a length of the conductive line to which the second light emitting devices are electrically connected can be controlled, thereby reducing the influence of the capacitance of the conductive line on the display quality. However, in a case where lengths of the conductive lines of different conductive layers are substantially the same, taking the conductive line structure shown in FIGS. 4 and 5 as an example, the extension portions of the conductive lines of the first conductive layer and the second conductive layer in the Y direction overlap, and the extension portion of the conductive line of the third conductive layer in the Y direction does not overlap with the extension portions of the conductive lines of the first conductive layer and the second conductive layer in the Y direction. There is a difference in mutual overlap areas between the conductive lines of the different conductive layers, which leads to differences in capacitance of the different conductive lines, and is likely to cause a problem such as uneven display.

An embodiment of the present disclosure provides a display panel. The display panel includes a base substrate and N conductive layers. N conductive layers are sequentially provided on the base substrate in a direction away from the base substrate, each conductive layer of the N conductive layers including at least one conductive line extending at least in a first direction, where N is an integer greater than or equal to 3. An orthographic projection of a portion of at least one conductive line extending in the first direction in each conductive layer on the base substrate and an orthographic projection of a portion of at least one conductive line extending in the first direction in remaining conductive layers on the base substrate are staggered and overlap in a second direction, and the second direction intersects with the first direction.

In a display panel provided by an embodiment of the present disclosure, an orthographic projection of a portion of at least one conductive line extending in the first direction in each conductive layer of N conductive layers on the base substrate and an orthographic projection of a portion of at least one conductive line extending in the first direction in the remaining conductive layers on the base substrate are staggered and overlap in the second direction, so as to improve the difference between multiple coupling capacitances generated by the multiple conductive lines in the N conductive layers and improve the display quality of the display panel.

In some exemplary implementations, the base substrate may be a flexible substrate, or may be a rigid substrate, for example a glass substrate, which is not limited by the present disclosure.

In an exemplary embodiment, an orthographic projection of one conductive line located in a nth conductive layer on the base substrate overlaps with an orthographic projection of one conductive line located in a (n−1)th conductive layer on the base substrate and an orthographic projection of one conductive line located in a (n+1)th conductive layer on the base substrate, and the orthographic projection of the conductive line located in the (n−1)th conductive layer on the base substrate does not overlap with the orthographic projection of the conductive line located in the (n+1)th conductive layer on the base substrate, in which n is an integer greater than or equal to 2 and less than or equal to N−1. In some examples, a value of N may be 3, and a value of n may be 2. An orthographic projection of a conductive line located in a second conductive layer on the base substrate overlaps with an orthographic projection of a conductive line located in a first conductive layer on the base substrate and an orthographic projection of a conductive line located in a third conductive layer on the base substrate, and the orthographic projection of the conductive line located in the first conductive layer on the base substrate may not overlap with the orthographic projection of the conductive line located in the third conductive layer on the base substrate.

In an exemplary embodiment, an overlapping length of the orthographic projection of the conductive line located in the nth conductive layer on the base substrate and the orthographic projection of the conductive line located in the (n−1)th conductive layer on the base substrate in the second direction is equal to an overlapping length of the orthographic projection of the conductive line located in the nth conductive layer on the base substrate and the orthographic projection of the conductive line located in the (n+1)th conductive layer on the base substrate in the second direction.

In an exemplary embodiment, the overlapping length of the orthographic projection of the conductive line located in the nth conductive layer on the base substrate and the orthographic projection of the conductive line located in the (n−1)th conductive layer on the base substrate in the second direction is

$$k 1 \times ( \frac{1}{2} W - \frac{1}{4} S ) ,$$

in which k1 is a first process parameter, W is a line width parameter, and S is a line spacing parameter.

In an exemplary embodiment, k1 is 0.7 to 1.3.

In an exemplary embodiment, an orthographic projection of one conductive line located in a mth conductive layer on the base substrate overlaps with an orthographic projection of one conductive line located in a (m−1)th conductive layer on the base substrate and an orthographic projection of one conductive line located in a (m−2)th conductive layer on the base substrate, and the orthographic projection of the conductive line located in the (m−1)th conductive layer on the base substrate does not overlap with the orthographic projection of the conductive line located in the (m−2)th conductive layer on the base substrate, in which m is an integer greater than or equal to 3 and less than or equal to N. In some examples, a value of N may be 3, and a value of m may be 3. An orthographic projection of a conductive line located in the third conductive layer on the base substrate may overlap with an orthographic projection of a conductive line located in the first conductive layer on the base substrate and an orthographic projection of a conductive line located in the second conductive layer on the base substrate, and the orthographic projection of the conductive line located in the first conductive layer on the base substrate may not overlap with the orthographic projection of the conductive line located in the second conductive layer on the base substrate.

In an exemplary embodiment, an overlapping length of the orthographic projection of the conductive line located in the mth conductive layer on the base substrate and the orthographic projection of the conductive line located in the (m−1)th conductive layer on the base substrate in the second direction is less than an overlapping length of the orthographic projection of the conductive line located in the mth conductive layer on the base substrate and the orthographic projection of the conductive line located in the (m−2)th conductive layer on the base substrate in the second direction.

In an exemplary embodiment, an overlapping length of the orthographic projection of the conductive line located in the mth conductive layer on the base substrate and the orthographic projection of the conductive line located in the (m−1)th conductive layer on the base substrate in the second direction is equal to a half of an overlapping length of the orthographic projection of the conductive line located in the mth conductive layer on the base substrate and the orthographic projection of the conductive line located in the (m−2)th conductive layer on the base substrate in the second direction.

In an exemplary embodiment, the overlapping length of the orthographic projection of the conductive line located in the mth conductive layer on the base substrate and the orthographic projection of the conductive line located in the (m−1)th conductive layer on the base substrate in the second direction is

$$k 2 ( W - \frac{1}{2} S ) ,$$

in which k2 is a second process parameter, W is a line width parameter, and S is a line spacing parameter.

In an exemplary embodiment, k2 is 0.7 to 1.3.

In an exemplary embodiment, k2 is equal to k1.

In an exemplary embodiment, line widths of the multiple conductive lines in at least one conductive layer are equal, and line spacings of adjacent conductive lines are equal.

In an exemplary embodiment, the line widths of the multiple conductive lines in at least one conductive layer are equal to the line spacings of adjacent conductive lines.

In an exemplary embodiment, line widths of conductive lines in different conductive layers are equal, and line spacings of adjacent conductive lines in different conductive layers are equal.

In an exemplary embodiment, an overlapping length of the orthographic projection of the conductive line located in the mth conductive layer on the base substrate and the orthographic projection of the conductive line located in the (m−1)th conductive layer on the base substrate in the second direction is denoted as Oₘ₋₁, an overlapping length of the orthographic projection of the conductive line located in the mth conductive layer on the base substrate and the orthographic projection of the conductive line located in the (m−2)th conductive layer on the base substrate in the second direction is denoted as Oₘ, and so on, in which if m is an integer greater than or equal to 3 and less than or equal to N, then O₁+O₂+ . . . +Oₘ=(m−1) W−S. Herein, W is a line width of conductive lines that are located in different conductive layers and whose orthographic projections on the base substrate overlap, S is a line spacing of conductive lines that are located in different conductive layers and whose orthographic projections on the base substrate overlap, and line widths of conductive lines that are located in different conductive layers and whose orthographic projections on the base substrate overlap are equal, and line spacings of conductive lines that are located in different conductive layers and whose orthographic projections on the base substrate overlap are equal.

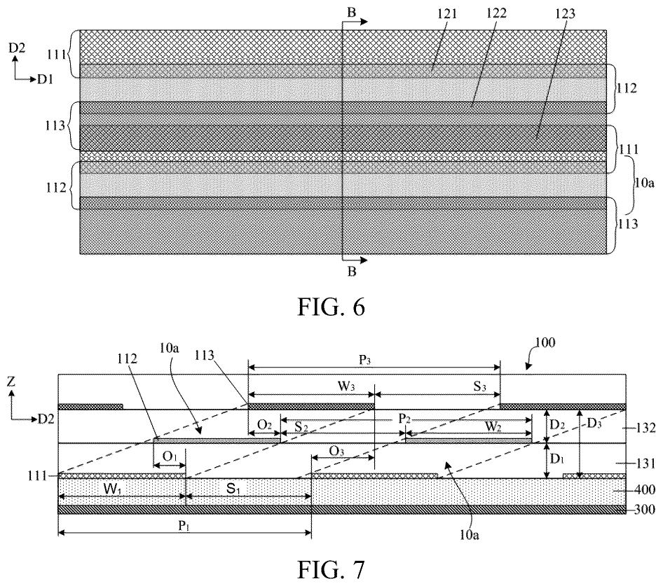

FIG. 6 is a schematic partial top view of a display panel according to an embodiment of the present disclosure. FIG. 7 is a schematic cross-sectional view of the display panel taken along B-B direction in FIG. 6. As shown in FIGS. 6 and 7, the technical solution is described only by taking the display panel including three conductive layers as an example. In a direction away from the base substrate, the three conductive layers may include a first conductive layer, a second conductive layer, and a third conductive layer provided sequentially in the direction away from the base substrate.

As shown in FIGS. 6 and 7, the first conductive layer includes at least one first conductive line 111 extending in the first direction D1. The second conductive layer may include at least one second conductive line 112 extending in the first direction D1. The third conductive layer may include at least one third conductive line 113 extending in the first direction D1. In an embodiment of the present disclosure, the first direction D1 may be parallel to the Y direction.

In an exemplary embodiment, as shown in FIGS. 6 and 7, the three conductive layers may include multiple conductive line groups 10a arranged at intervals. One conductive line group 10a may include three conductive lines located in different conductive layers. In the thickness direction (Z direction) of the display panel, one conductive line group 10a may include one first conductive line 111, one second conductive line 112, and one third conductive line 113 which are stacked sequentially. Three conductive lines in one conductive line group 10a are staggered sequentially in the second direction D2.

In an exemplary embodiment, as shown in FIG. 6, an orthographic projection of a portion of at least one conductive line extending in the first direction D1 in each conductive layer on the base substrate and an orthographic projection of a portion of at least one conductive line extending in the first direction D1 in the remaining conductive layers on the base substrate are staggered and overlap in the second direction D2. In an embodiment of the present disclosure, the second direction D2 may be parallel to the X direction.

As shown in FIG. 6, an orthographic projection of a portion of the first conductive line 111 extending in the first direction on the base substrate and an orthographic projection of a portion of the second conductive line 112 extending in the first direction on the base substrate in a same conductive line group 10a overlap in the second direction, and the overlap is denoted as a first overlap 121, that is, there is an overlapping wire. An orthographic projection of a portion of the second conductive line 112 extending in the first direction on the base substrate and an orthographic projection of a portion of the third conductive line 113 extending in the first direction on the base substrate in a same conductive line group 10a overlap in the second direction, and the overlap is denoted as a second overlap 122, that is, there is an overlapping wire. As shown in FIG. 6, the first overlap 121 staggers from the second overlap 122 in the second direction, that is, the first overlap 121 does not intersect with the second overlap 122.

In an exemplary embodiment, as shown in FIG. 6, an orthographic projection of a portion of the third conductive line 113 in a conductive line group 10a extending in the first direction on the base substrate and an orthographic projection of a portion of the first conductive line 111 in another adjacent conductive line group 10a extending in the first direction on the base substrate overlap in the second direction, and the overlap is denoted as a third overlap 123, that is, there is an overlapping wire. As shown in FIG. 7, an orthographic projection of a portion of a second conductive line 112 extending in the first direction in a same conductive line group 10a as the third conductive line 113 on the base substrate and an orthographic projection of a portion of a first conductive line 111 extending in the first direction in another adjacent conductive line group 10a on the base substrate do not overlap in the second direction.

In an exemplary embodiment, the first conductive line 111, the second conductive line 112, and the third conductive line 113 may all adopt a transparent conductive material. By way of example, the transparent conductive material may adopt a conductive oxide material, for example indium tin oxide (ITO), which is not limited by the present disclosure.

In an exemplary embodiment, a thickness of the first conductive layer may be set to be less than 0.1 microns. A thickness of the second conductive layer may be set to be less than 0.1 microns. A thickness of the third conductive layer may be set to be less than 0.1 microns.

In an exemplary embodiment, as shown in FIG. 7, only two conductive line groups 10a which are schematically illustrated is taken as an example. In an embodiment of the present disclosure, a length of the first overlap 121 is denoted as O₁, a length of the second overlap 122 is denoted as O₂, and a length of the third overlap 123 is denoted as O₃. By way of example, O₁, O₂ and O₃ may be different form each other.

In an exemplary embodiment, as shown in FIG. 7, O₁ may be equal to O₂.

In an exemplary embodiment, as shown in FIG. 7, O₃ may be greater than O₁, and greater than O₂. By way of example, O₁ may be equal to O₂, and O₃ may be equal to 2O₁.

In an exemplary embodiment, as shown in FIG. 7, a line width of the first conductive line 111 is denoted as W₁, a line spacing of two adjacent first conductive lines 111 in the first conductive layer is denoted as S₁, and an occupying width of the first conductive line 111 in the first conductive layer is denoted as P₁, then P₁ is equal to a sum of W₁ and S₁. A line width of the second conductive line 112 is denoted as W₂, a line spacing of two adjacent second conductive lines 112 in the second conductive layer is denoted as S₂, and an occupying width of the second conductive line 112 in the second conductive layer is denoted as P₂, then P₂ is equal to a sum of W₂ and S₂. A line width of the third conductive line 113 is denoted as W₃, a line spacing of two adjacent third conductive lines 113 in the third conductive layer is denoted as S₃, and an occupying width of the third conductive line 113 in the third conductive layer is denoted as P₃, then P₃ is equal to a sum of W₃ and S₃. By way of example, P₁, P₂, and P₃ are equal to each other.

In an exemplary embodiment, the line width W₁ and the line spacing S₁ of the first conductive line 111 may be determined according to an actual process capability, and the present disclosure is not limited thereto. According to conventional process capabilities and design requirements, generally, S₁ is less than 2W₁. By way of example, the line width W₂ and the line spacing S₂ of the second conductive lines 112 may be set with reference to the line width W₁ and the line spacing S₁ of the first conductive lines 111. By way of example, W₂ and W₃ may be set to be the same as W₁, and are both denoted as W, and W is also known as the line width parameter. S₂ and S₃ may be set to be the same as S₁, and are both denoted as S, and S is also known as the line spacing parameter. By setting the same line widths and the same line spacings of the first conductive lines 111, the second conductive lines 112, and the third conductive lines 113, the complexity of the manufacturing process of the conductive line may be reduced, and the manufacturing cost of the display panel may be reduced.

In an exemplary embodiment, as shown in FIG. 7, the display panel may further include a first insulation layer 131 located on a side of the first conductive layer away from the base substrate. The first insulation layer 131 may be located between the first conductive layer and the second conductive layer. An orthographic projection of the first insulation layer 131 on the base substrate covers an orthographic projection of a portion of the first conductive line 111 extending in the first direction on the base substrate, which can avoid signal crosstalk between the first conductive line 111 and the second conductive line 112. As shown in FIG. 7, a thickness of the first insulation layer 131 is denoted as D₁.

In an exemplary embodiment, a thickness of the first insulation layer 131 may be set to 1.0 micron to 3.0 microns.

In an exemplary embodiment, a thickness of the first conductive layer may be less than a thickness of the first insulation layer 131.

In an exemplary embodiment, the first insulation layer 131 may be made of an inorganic material. The inorganic material may include any one or more of silicon oxynitride (SiOXNy), silicon nitride (SiN), silicon oxide (SiO), silicon dioxide (SiO₂), aluminum oxide (Al₂O₃), titanium dioxide (TiO₂), niobium pentoxide (Nb₂O₅) and the like.

In an exemplary embodiment, the first insulation layer 131 may be made of an organic material. The organic material may include one of polyimide (PI), polyacrylate, polyphenylene sulfide, polyarylester, cellulose acetate propionate, polyethylene naphthalate (PEN), polyethylene terephthalate (PET), polyethersulfone resin (PES), polycarbonate (PC), polyetherimide (PEI), cycloolefin polymer (COP), silica gel resin, polyaryl compound (PAR) or glass fiber reinforced plastic (FRP) or other polymers, or a mixture of multiple polymers.

In an exemplary embodiment, the first insulation layer 131 may be provided as a single-layer film layer, or a composite film layer, or the like.

In an exemplary embodiment, as shown in FIG. 7, the display panel may further include a second insulation layer 132 located on a side of the second conductive layer away from the base substrate. The second insulation layer 132 may be located between the second conductive layer and the third conductive layer. An orthographic projection of the second insulation layer 132 on the base substrate covers an orthographic projection of a portion of the second conductive line 112 extending in the first direction on the base substrate, which can avoid signal crosstalk between the second conductive line 112 and the third conductive line 113. As shown in FIG. 7, a thickness of the second insulation layer 132 is denoted by D₂. As shown in FIG. 7, a thickness of an insulation layer between the first conductive layer and the third conductive layer is denoted as D₃. By way of example, D₂ may be equal to D₁, and D₂ and D₁ may all be denoted as D. D₃ may be equal to a sum of D₁ and D₂, i.e., D₃ may be equal to 2D.

In an exemplary embodiment, a thickness and a material of the second insulation layer 132 may be set with reference to the first insulation layer 131, and the present disclosure is not limited thereto.

In an exemplary embodiment, a thickness of the first insulation layer 131 may be different from a thickness of the second insulation layer 132.

In an exemplary embodiment, a thickness of the second conductive layer may be less than a thickness of the second insulation layer 132.

In an exemplary embodiment, a thickness of the conductive layer is less than a thickness of the insulation layer adjacent to the conductive layer. The adjacent insulation layer may be located on a side of the conductive layer close to the base substrate or on a side of the conductive layer away from the base substrate.

In an exemplary embodiment, as shown in FIG. 7, in a direction perpendicular to the display panel, the display panel may include a base substrate 300, and a circuit structure layer 400, a first conductive layer, a second conductive layer, a third conductive layer, and a light emitting structure layer provided on a side of the base substrate 300. The circuit structure layer 400 may include multiple pixel driving circuits. A first insulation layer 131 may be provided between the first conductive layer and the second conductive layer and a second insulation layer 132 may be provided between the second conductive layer and the third conductive layer. A third insulation layer may be provided between the third conductive layer and the light emitting structure layer. The light emitting structure layer may include an anode layer, a pixel define layer, an organic emitting layer, and a cathode layer.

In an exemplary embodiment, a coupling capacitance of the first conductive line 111 located in the first conductive layer and the second conductive line 112 located in the second conductive layer, and the third conductive line 113 located in the third conductive layer may be denoted as C₁, a coupling capacitance of the second conductive line 112 located in the second conductive layer and the first conductive line 111 located in the first conductive layer, and the third conductive line 113 located in the third conductive layer may be denoted as C₂, and a coupling capacitance of the third conductive line 113 located in the third conductive layer and the first conductive line 111 located in the first conductive layer, and the second conductive line 112 located in the second conductive layer may be denoted as C₃. The following equations may be satisfied between related parameters: P₁=W₁+S₁, P₂=W₂+S₂, and P₃=W₃+S₃.

W₁=W₂=W₃ are set, and W₁, W₂ and W₃ are all denoted as W. S₁=S₂=S₃ are set, and S₁, S₂ and S₃ are all denoted as S, and W₁+W₂+W₃−O₁-O₂−O₃=P₁=W₁+S₁, that is 3W−O₁-O₂−O₃=W+S.

According to the above relationship, equation (1) can be derived:

$$2 W - S = {O}_{1} + {O}_{2} + {O}_{3} \qquad ( 1 )$$

In general, when the first insulation layer 131 and the second insulation layer 132 are manufactured using a same material and under the same process conditions, the dielectric constants of the film interlayer capacitance are the same. Thicknesses of the first insulation layer 131 and the second insulation layer 132 are set to be the same, that is: D₁=D₂, D₃=D₁+D₂=2D₁.

To make C₁=C₂=C₃, then the following equation (2) needs to be satisfied:

$$\frac{{O}_{1}}{{D}_{1}} + \frac{{O}_{3}}{{D}_{3}} = \frac{{O}_{1}}{{D}_{1}} + \frac{{O}_{2}}{{D}_{2}} = \frac{{O}_{2}}{{D}_{2}} + \frac{{O}_{3}}{{D}_{3}}$$

According to D₁=D₂, and D₃=D₁+D₂=2D₁, equation (3) may be derived:

O₁=O₂, and O₃=2O₁ (3)

By bringing equation (3) into equation (1), the following can be obtained:

$${O}_{1} = {O}_{2} = 1 / 2 W - 1 / 4 S , and {O}_{3} = 2 {O}_{1} = W - 1 / 2 S .$$

In the above derivation process, D₁=D₂, and D₃=D₁+D₂=2D₁ is only one usage scenario in practical application. According to an actual structural design need of the display panel, the numerical relationships between D₁, D₂, and D₃ may be any combination, O₁, O₂ and O₃ may be calculated in combination with the above equation (2), and the present disclosure is not limited thereto.

Taking a certain display panel as an example, it is known that P₁ is 3.8 microns, W₁ and S₁ are both 1.9 microns, then O₁ is 0.475 microns, O₂ is 0.475 microns, and O₃ is 0.95 microns, that is O₃ is equal to 2O₁. Since the thickness and process of the first insulation layer 131 and the second insulation layer 132 are the same, according to the above relationships between O₁, O₂, and O₃, it can be concluded that C₁, C₂ and C₃ are all equal.

Taking another display panel as an example, it is known that P₁ is 3.8 microns, W₁ is 2.0 microns, S₁ is 1.8 microns, then O₁ is 0.55 microns, O₂ is 0.55 microns, and O₃ is 1.1 microns, that is, O₃ is equal to 2O₁. Since the thickness and process of the first insulation layer 131 and the second insulation layer 132 are the same, according to the above relationships between O₁, O₂, and O₃, it can still be concluded that C₁, C₂ and C₃ are all equal.

In an exemplary embodiment, O₁, O₂ and O₃ obtained according to the above calculation are all corresponding theoretical values, and the actual values may be obtained by multiplying the process parameters on the basis of the theoretical values. By way of example, O₃=k2×(W−½S, in which k2 is a second process parameter, and k2 is from 0.7 to 1.3. W is the line width parameter and S is the line spacing parameter. The actual value is used to guide the actual production and manufacture of the display panel. Because the actual value has fully considered the machining accuracy and dimensional fluctuation of the display panel in the actual production and manufacture process on the basis of the theoretical value, the product design is more reasonable, which is beneficial to reducing the manufacturing cost of the display panel.

A structure of the display panel will now be described through an example of a manufacturing process of the display panel. A “patterning process” mentioned in the embodiments of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a material on a base substrate by using deposition, coating, or another process. If the “thin film” does not need to be processed by a patterning process in the entire manufacturing process, the “thin film” may also be called a “layer”. If the “thin film” needs to be processed by the patterning process in the entire manufacturing process, the “thin film” is called a “thin film” before the patterning process is performed and is called a “layer” after the patterning process is performed. At least one “pattern” is contained in the “layer” which has been processed by the patterning process.

A process of manufacturing the display panel may include the following steps:
(1) Providing a base substrate.
(2) Forming a semiconductor layer.

A semiconductor thin film is deposited on a base substrate and the semiconductor thin film is patterned by a patterning process to form a semiconductor layer.
(3) Forming a first gate metal layer.

A first insulation thin film and a first metal thin film are sequentially deposited on the base substrate on which the aforementioned structures are formed and the first metal thin film is patterned by a patterning process to form the first insulation layer covering the semiconductor layer and the first gate metal layer provided on the first insulation layer.
(4) Forming a second gate metal layer.

A second insulation thin film and a second metal thin film are sequentially deposited on the base substrate on which the aforementioned structures are formed and the second metal thin film is patterned by a patterning process to form the second insulation layer covering the first gate metal layer and the second gate metal layer provided on the second insulation layer.
(5) Forming a third insulation layer and a first source-drain metal layer.

A third insulation thin film is deposited on the base substrate on which the aforementioned structures are formed, and the third insulation layer is formed by a patterning process. The third insulation layer is provided with multiple pixel vias. Subsequently, a third metal thin film is deposited, and the third metal thin film is patterned by a patterning process to form the first source-drain metal layer provided on the third insulation layer.
(6) Forming a second source-drain metal layer.

A fourth insulation thin film and a fourth metal thin film are sequentially deposited on the base substrate on which the aforementioned structures are formed, and the fourth metal thin film is patterned by a patterning process to form a fourth insulation layer covering the first source-drain metal layer, and the second source-drain metal layer provided on the fourth insulation layer.

In some exemplary implementations, a fifth insulation thin film is coated on the base substrate on which the aforementioned structures are formed, and a fifth insulation layer is formed by a patterning process.
(7) Forming a first conductive layer.

A first transparent conductive thin film is deposited on the base substrate on which the aforementioned structures are formed, and the first transparent conductive thin film is patterned by a patterning process to form the first conductive layer provided on the fifth insulation layer.
(8) Forming a sixth insulation layer and a second conductive layer.

A sixth insulation thin film is coated on the base substrate on which the aforementioned structures are formed, and the sixth insulation layer (that is, the aforementioned first insulation layer 131) is formed by a patterning process. Subsequently, a second transparent conductive thin film is deposited, and the second transparent conductive thin film is patterned by a patterning process to form the second conductive layer provided on the sixth insulation layer.
(9) Forming a seventh insulation layer and a third conductive layer.

A seventh insulation thin film is coated on the substrate on which the aforementioned structure is formed, and a seventh insulation layer (that is, the aforementioned second insulation layer 132) is formed by a patterning process. Subsequently, a third transparent conductive thin film is deposited, and the third transparent conductive thin film is patterned by a patterning process to form the third conductive layer provided on the seventh insulation layer.
(10) Forming a light emitting structure layer.

An eighth insulation thin film is coated on the base substrate on which the aforementioned structures are formed, and an eighth insulation layer is formed by a patterning process. Subsequently, an anode conductive thin film is deposited, and the anode conductive thin film is patterned by a patterning process to form an anode layer provided on the eighth insulation layer. Subsequently, a pixel define thin film is coated on the base substrate on which the aforementioned patterns are formed, and a Pixel Define Layer (PDL) is formed by masking, exposure and development processes. The pixel define layer is formed with multiple pixel openings exposing the anode layer. An organic emitting layer is formed in the aforementioned pixel openings, and the organic emitting layer is connected with an anode. Subsequently, a cathode thin film is deposited, and the cathode thin film is patterned by a patterning process to form a cathode pattern. Subsequently, an encapsulation layer is formed on the cathode.

An embodiment of the present disclosure provides a manufacturing method for a display panel. The manufacturing method is applied to the manufacturing for the display panel according to any one of the aforementioned embodiments. The manufacturing method includes sequentially forming N conductive layers on a side of the base substrate. Each conductive layer of the N conductive layers includes at least one conductive line extending at least in the first direction, and N is an integer greater than or equal to 3. An orthographic projection of a portion of at least one conductive line extending in the first direction in each conductive layer on the base substrate and an orthographic projection of a portion of at least one conductive line extending in the first direction in the remaining conductive layers on the base substrate are staggered and overlap in a second direction.

An embodiment of the present disclosure further provides a display apparatus which includes the display panel according to any one of aforementioned embodiments. In some examples, the display panel may include an OLED display substrate, a QLED display substrate, a Micro-LED display substrate, or a Mini-LED display substrate. The display apparatus may be any product or component with a display function, such as a mobile phone, a tablet computer, a television, a display, a laptop computer, a digital photo frame, or a navigator. However, the present embodiment is not limited thereto.

Although the embodiments disclosed in the present disclosure are described as above, the described contents are only embodiments which are adopted in order to facilitate understanding of the present disclosure, and are not intended to limit the present disclosure. It should be noted that the above examples or embodiments are exemplary only but not restrictive. Therefore, the present disclosure is not limited to what is specifically shown and described herein. Various modifications, substitutions or omissions may be made in forms and details of implementations without departing from the scope of the present disclosure.

1. A display panel, comprising:
a base substrate;
N conductive layers, sequentially provided on the base substrate in a direction away from the base substrate, wherein each conductive layer of the N conductive layers comprises at least one conductive line extending at least in a first direction, and N is an integer greater than or equal to 3; and
wherein an orthographic projection of a portion of at least one conductive line extending in the first direction in each conductive layer on the base substrate and an orthographic projection of a portion of at least one conductive line extending in the first direction in remaining conductive layers on the base substrate are staggered and overlap in a second direction, and the second direction intersects with the first direction.

2. The display panel according to claim 1, wherein an orthographic projection of one conductive line located in a nth conductive layer on the base substrate overlaps with an orthographic projection of one conductive line located in a (n−1)th conductive layer on the base substrate and an orthographic projection of one conductive line located in a (n+1)th conductive layer on the base substrate, and the orthographic projection of the conductive line located in the (n−1)th conductive layer on the base substrate does not overlap with the orthographic projection of the conductive line located in the (n+1)th conductive layer on the base substrate, wherein n is an integer greater than or equal to 2 and less than or equal to N−1.

3. The display panel according to claim 2, wherein an overlapping length of the orthographic projection of the conductive line located in the nth conductive layer on the base substrate and the orthographic projection of the conductive line located in the (n−1)th conductive layer on the base substrate in the second direction is equal to an overlapping length of the orthographic projection of the conductive line located in the nth conductive layer on the base substrate and the orthographic projection of the conductive line located in the (n+1)th conductive layer on the base substrate in the second direction.

4. The display panel according to claim 3, wherein the overlapping length of the orthographic projection of the conductive line located in the nth conductive layer on the base substrate and the orthographic projection of the conductive line located in the (n−1)th conductive layer on the base substrate in the second direction is
$$k 1 \times ( \frac{1}{2} W - \frac{1}{4} S ) ,$$
wherein k1 is a first process parameter, W is a line width parameter, and S is a line spacing parameter.

5. The display panel according to claim 1, wherein an orthographic projection of one conductive line located in a mth conductive layer on the base substrate overlaps with an orthographic projection of one conductive line located in a (m−1)th conductive layer on the base substrate and an orthographic projection of one conductive line located in a (m−2)th conductive layer on the base substrate, and the orthographic projection of the conductive line located in the (m−1)th conductive layer on the base substrate does not overlap with the orthographic projection of the conductive line located in the (m−2)th conductive layer on the base substrate, wherein m is an integer greater than or equal to 3 and less than or equal to N.

6. The display panel according to claim 5, wherein an overlapping length of the orthographic projection of the conductive line located in the mth conductive layer on the base substrate and the orthographic projection of the conductive line located in the (m−1)th conductive layer on the base substrate in the second direction is less than an overlapping length of the orthographic projection of the conductive line located in the mth conductive layer on the base substrate and the orthographic projection of the conductive line located in the (m−2)th conductive layer on the base substrate in the second direction.

7. The display panel according to claim 6, wherein the overlapping length of the orthographic projection of the conductive line located in the mth conductive layer on the base substrate and the orthographic projection of the conductive line located in the (m−1)th conductive layer on the base substrate in the second direction is equal to a half of the overlapping length of the orthographic projection of the conductive line located in the mth conductive layer on the base substrate and the orthographic projection of the conductive line located in the (m−2)th conductive layer on the base substrate in the second direction.

8. The display panel according to claim 7, wherein the overlapping length of the orthographic projection of the conductive line located in the mth conductive layer on the base substrate and the orthographic projection of the conductive line located in the (m−1)th conductive layer on the base substrate in the second direction is
$$k 2 \times ( W - \frac{1}{2} S ) ,$$
wherein k2 is a second process parameter, W is a line width parameter, and S is a line spacing parameter.

9. The display panel according to claim 1, wherein line widths of a plurality of conductive lines in at least one conductive layer are equal, and line spacings of adjacent conductive lines are equal.

10. The display panel according to claim 9, wherein the line widths of the plurality of conductive lines in the at least one conductive layer are equal to the line spacings of adjacent conductive lines.

11. The display panel according to claim 9, wherein line widths of conductive lines in different conductive layers are equal, and line spacings of adjacent conductive lines in different conductive layers are equal.

12. The display panel according to claim 1, wherein the display panel further comprises an insulation layer between two adjacent conductive layers, and a plurality of insulation layers have equal thicknesses.

13. The display panel according to claim 12, wherein a thickness of the conductive layer is less than a thickness of the insulation layer adjacent to the conductive layer.

14. The display panel according to claim 1, wherein the display panel comprises a display area; the display area comprises a first area and a second area; an orthographic projection of the first area on the base substrate does not overlap with an orthographic projection of the second area on the base substrate;
the display panel further comprises: a circuit structure layer and a light emitting structure layer provided on the base substrate, the light emitting structure layer is located on a side of the circuit structure layer away from the base substrate, and the N conductive layers are located between the circuit structure layer and the light emitting structure layer; the circuit structure layer comprises: a plurality of first pixel driving circuits and a plurality of second pixel driving circuits located in the first area, and the light emitting structure layer comprises: a plurality of first light emitting devices located in the first area and a plurality of second light emitting devices located in the second area; and
at least one first pixel driving circuit of the plurality of first pixel driving circuits is electrically connected to at least one first light emitting device of the plurality of first light emitting devices, and at least one second pixel driving circuit of the plurality of second pixel driving circuits is electrically connected to at least one second light emitting device of the plurality of second light emitting devices by at least one conductive line in the N conductive layers.

15. The display panel according to claim 1, wherein a value of N is 3;
an orthographic projection of one conductive line located in a second conductive layer on the base substrate overlaps with an orthographic projection of one conductive line located in a first conductive layer on the base substrate and an orthographic projection of one conductive line located in a third conductive layer on the base substrate, and the orthographic projection of the conductive line located in the first conductive layer on the base substrate does not overlap with the orthographic projection of the conductive line located in the third conductive layer on the base substrate; the orthographic projection of the conductive line located in the third conductive layer on the base substrate overlaps with an orthographic projection of another conductive line located in the first conductive layer on the base substrate, and the conductive line and the another conductive line located in the first conductive layer are adjacent to each other in the second direction.

16. The display panel according to claim 15, wherein an overlapping length of the orthographic projection of the conductive line located in the second conductive layer on the base substrate and the orthographic projection of the conductive line located in the first conductive layer on the base substrate in the second direction is equal to an overlapping length of the orthographic projection of the conductive line located in the second conductive layer on the base substrate and the orthographic projection of the conductive line located in the third conductive layer on the base substrate in the second direction; and
an overlapping length of the orthographic projection of the conductive line located in the third conductive layer on the base substrate and the orthographic projection of the another conductive line located in the first conductive layer on the base substrate in the second direction is equal to two times of the overlapping length of the orthographic projection of the conductive line located in the second conductive layer on the base substrate and the orthographic projection of the conductive line located in the first conductive layer on the base substrate in the second direction.

17. The display panel according to claim 15, wherein an overlapping length of the orthographic projection of the conductive line located in the second conductive layer on the base substrate and the orthographic projection of the conductive line located in the first conductive layer on the base substrate in the second direction is denoted as O₁; an overlapping length of the orthographic projection of the conductive line located in the second conductive layer on the base substrate and the orthographic projection of the conductive line located in the third conductive layer on the base substrate in the second direction is denoted as O₂; an overlapping length of the orthographic projection of the conductive line located in the third conductive layer on the base substrate and the orthographic projection of the another conductive line located in the first conductive layer on the base substrate in the second direction is denoted as O₃; a thickness of an insulation layer between the first conductive layer and the second conductive layer is denoted as D₁; a thickness of an insulation layer between the second conductive layer and the third conductive layer is denoted as D₂; a thickness of an insulation layer between the first conductive layer and the third conductive layer is denoted as D₃; then O₁, O₂, O₃, D₁, D₂ and D₃ satisfy the following equations:
$$\frac{{O}_{1}}{{D}_{1}} + \frac{{O}_{3}}{{D}_{3}} = \frac{{O}_{1}}{{D}_{1}} + \frac{{O}_{2}}{{D}_{2}} = \frac{{O}_{2}}{{D}_{2}} + \frac{{O}_{3}}{{D}_{3}} .$$

18. A display apparatus, comprising the display panel according to claim 1.

19. A manufacturing method for a display panel, which is used for manufacturing the display panel according to claim 1, wherein the manufacturing method comprises:
sequentially forming N conductive layers on a side of a base substrate; wherein each conductive layer of the N conductive layers comprises at least one conductive line extending at least in a first direction, and N is an integer greater than or equal to 3; an orthographic projection of a portion of at least one conductive line extending in the first direction in each conductive layer on the base substrate and an orthographic projection of a portion of at least one conductive line extending in the first direction in remaining conductive layers on the base substrate are staggered and overlap in a second direction, and the second direction intersects with the first direction.

20. The display panel according to claim 2, wherein an orthographic projection of one conductive line located in a mth conductive layer on the base substrate overlaps with an orthographic projection of one conductive line located in a (m−1)th conductive layer on the base substrate and an orthographic projection of one conductive line located in a (m−2)th conductive layer on the base substrate, and the orthographic projection of the conductive line located in the (m−1)th conductive layer on the base substrate does not overlap with the orthographic projection of the conductive line located in the (m−2)th conductive layer on the base substrate, wherein m is an integer greater than or equal to 3 and less than or equal to N.
